(19) United States
(12) Patent Application Publication
(10) Pub. No.: US 2013/0234746 A1
(43) Pub. Date: Sep. 12, 2013

(54) SHIELDED PROBE ARRAY

(71) Applicant: ADVANTEST CORPORATION, Tokyo (JP)

(72) Inventor: Lakshmikanth NAMBURI, Arcadia, CA (US)

(73) Assignee: ADVANTEST CORPORATION, Tokyo (JP)

(21) Appl. No.: 13/788,975

(22) Filed: Mar. 7, 2013

Related U.S. Application Data
(63) Continuation-in-part of application No. 13/744,190, filed on Jan. 17, 2013.
(60) Provisional application No. 61/607,879, filed on Mar. 7, 2012.
(60) Provisional application No. 61/727,039, filed on Nov. 15, 2012.

(51) Int. Cl. G01R 1/073

(52) U.S. Cl. CPC G01R 1/07307
USPC 324/750.25; 324/755.01; 324/750.26; 427/58; 156/60

(57) ABSTRACT

Shielded probe array. In accordance with a first embodiment, an article of manufacture includes a plurality of rows of electronic probes. Each row of probes is substantially in a plane. Each probe includes a metal signal layer and a ground layer, separated by an insulator. The article of manufacture also includes a space transformer for mechanically supporting the plurality of rows of electronic probes. The space transformer also provides an electrical path from each of the probe metal signal layers and the probe ground layers to a higher level electronic assembly. Each of the plurality of rows of electronic probes may include a handle including a substrate for handling the row of electronic probes.

### RELATED APPLICATIONS

This application claims priority to U.S. Provisional Patent Application 61/607,879, entitled, “Shielded 2D Probe Arrays Stacked to Form 3D Probe Arrays,” filed 7 Mar. 2012, to Namburi, which is hereby incorporated herein by reference in its entirety.

This application claims priority to U.S. Provisional Patent Application 61/727,039, entitled, “Fine Pitch Probes for Semiconductor Testing and a Method to Fabricate and Assemble Same,” filed 15 Nov. 2012, to Cros et al., which is hereby incorporated herein by reference in its entirety.

This application is a Continuation in Part of, and claims priority to co-pending, commonly-owned U.S. patent application Ser. No. 13/744,190, entitled “Fine Pitch Probes for Semiconductor Testing, and a Method to Fabricate and Assemble Same,” filed 17 Jan. 2013, to Cros, Namburi and Hu, which is hereby incorporated herein by reference in its entirety.

### FIELD OF INVENTION

Embodiments of the present invention relate to the field of integrated circuit design, manufacture and test. More specifically, embodiments of the present invention relate to systems and methods for shielded probe arrays.

### BACKGROUND

Integrated circuit testing generally utilizes fine probes to make contact with test points of an integrated circuit in order to inject electrical signals and/or measure electrical parameters of the integrated circuit. Conventional circuit probes are produced singly, and manually assembled into an array corresponding to some or all of the test points on an integrated circuit.

Unfortunately, due to the constraints of producing the probes individually, and assembling them into an array, conventional integrated circuit probe arrays are generally unable to achieve a pitch, e.g., probe to probe spacing, of less than about 50 μm. Further, conventional integrated circuit probe arrays are typically unable to achieve necessary alignment accuracies in all three dimensions. Still further, such alignment and co-planarity deficiencies of conventional probes deleteriously limit the number of probes and the total area of a probe array, and hence the total area of an integrated circuit that may be tested at a single time. For example, a single conventional integrated circuit probe array may not be capable of contacting all test points on a large integrated circuit, e.g., an advanced microprocessor.

In addition, conventional probes often are too long and have an undesirable high inductance, which may limit the suitability of such probes for use with high frequency signals. In addition, for high frequency probing applications the probes should be shielded. However, the fine pitch and tight geometries of such probes make it very difficult to manufacture probes with a shield, and to electrically ground such a shield.

### SUMMARY OF THE INVENTION

Therefore, what is needed are systems and methods for shielded probe arrays. What is additionally needed are systems and methods for shielded probe arrays that provide an electrically grounded shield at fine pitch geometries. A further need exists for systems and methods for shielded probe arrays that are compatible and complementary with existing systems and methods of integrated circuit design, manufacturing and test. Embodiments of the present invention provide these advantages.

In contrast to the conventional art in which an array of electronic probes is constructed by adding individually formed probes that are then combined to form an assembly, embodiments in accordance with the present invention form rows of shielded electronic probes via microelectromechanical systems (MEMS) processes, which are then stacked to form an array of probes.

In accordance with a first embodiment, an article of manufacture includes a plurality of rows of electronic probes. Each probe is substantially in a plane. Each row of probes includes a metal signal layer and a ground layer, separated by an insulator. The article of manufacture also includes a space transformer for mechanically supporting the plurality of rows of electronic probes. The space transformer also provides an electrical path from each of the probe metal signal layers and the probe ground layers to a higher level electronic assembly. Each of the plurality of rows of electronic probes may include a handle including a substrate for handling the row of electronic probes.

In accordance with a method embodiment, a substrate is coated with an insulating layer. A first conductive pattern, including an area pattern and a plurality of finger patterns, is deposited onto the insulating layer, the fingers patterns separate from one another but electrically coupled to the area pattern. A dielectric pattern is applied on top of the conductive pattern. The dielectric pattern substantially conforms to the finger patterns, and extends a pattern of the fingers across and beyond the area pattern to form a nub pattern. A second conductive pattern is plated on top of and coincident to the dielectric pattern. A probe tip is plated on top of the second conductive pattern. Portions of the substrate and the insulating area under the finger pattern and the nub pattern are removed to form a row of probes.

In accordance with another embodiment of the present invention, an array of shielded probes for probing an integrated circuit includes at least two probes, characterized as being separated by a probe pitch distance. The probes include a signal conductor and a shield conductor, electrically isolated from each other. The probes also include a probe tip, electrically connected to the signal conductor, comprising a different material from the signal conductor. The array of shielded probes also includes a space transformer for coupling signals from the at least two signal conductors to contacts separated by greater than the probe pitch distance.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not drawn to scale.

FIG. 1 illustrates a plan view of a portion of an exemplary substrate, e.g., a silicon or silicon on insulator (SOI) wafer, coated with an insulating layer, e.g., an oxide, in accordance with embodiments of the present invention.

FIG. 2 illustrates a plan view of an exemplary patterned metal ground plane formed on top of the substrate, in accordance with embodiments of the present invention.

FIG. 3 illustrates a plan view of an exemplary patterned insulator, e.g., an oxide, deposited on top of a portion of the ground pattern, including fingers, in accordance with embodiments of the present invention.

FIG. 4 illustrates a plan view of an exemplary patterned probe metal on top of the oxide layer, in accordance with embodiments of the present invention.

FIG. 5 illustrates a plan view of an exemplary application of a patterned probe tip over probe metal, in accordance with embodiments of the present invention.

FIG. 6 illustrates a cross sectional view of an exemplary probe finger at the tip, in accordance with embodiments of the present invention.

FIG. 7 illustrates a plan view of an exemplary row of probes, in accordance with embodiments of the present invention.

FIG. 8 illustrates a cross sectional view of exemplary row of probes, in accordance with embodiments of the present invention.

FIG. 9 illustrates a cross sectional view of an exemplary stack of a plurality of rows of probes, in accordance with embodiments of the present invention.

FIG. 10 illustrates a cross sectional view of an exemplary shielded probe array, in accordance with embodiments of the present invention.

### DETAILED DESCRIPTION

Reference will now be made in detail to various embodiments of the present invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of AN ARTICLE OF MANUFACTURE ordinary skill in the art that the invention may be practiced without these specific details. In other instances, well known methods, procedures, components, and circuits have not been described in detail as not to unnecessarily obscure aspects of the invention.

### NOTATION AND NOMENCLATURE

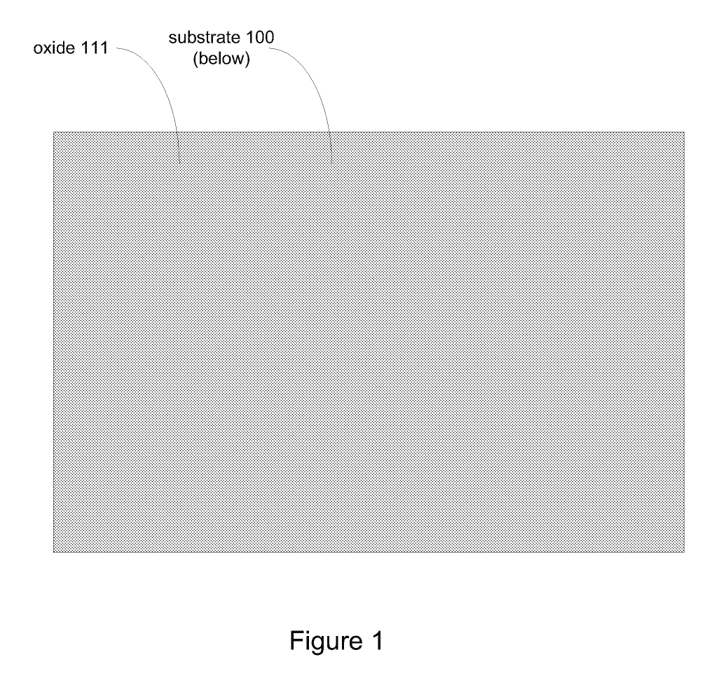

Some portions of the detailed descriptions which follow (e.g., FIGS. 1-10) are presented in terms of procedures, steps, logic blocks, processing, and other symbolic representations of operations on data bits that may be performed on computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “accessing” or “forming” or “mounting” or “removing” or “coating” or “attaching” or “processing” or “singulating” or “roughening” or “filling” or “performing” or “generating” or “adjusting” or “creating” or “executing” or “continuing” or “indexing” or “computing” or “translating” or “calculating” or “determining” or “measuring” or “gathering” or “running” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

### Shielded Probe Array

FIG. 1 illustrates a plan view of a portion of an exemplary substrate 100, e.g., a silicon or silicon on insulator (SOI) wafer, coated with an insulating layer, e.g., an oxide 111, in accordance with embodiments of the present invention.

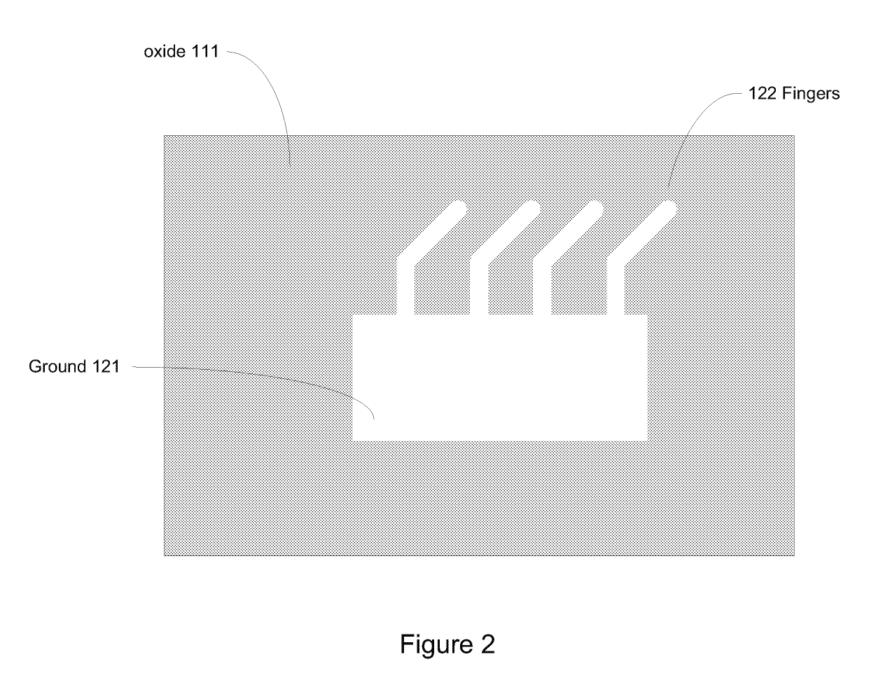

FIG. 2 illustrates a plan view of an exemplary patterned metal ground plane 121 formed on top of the substrate 100, in accordance with embodiments of the present invention. The pattern comprises a large area, e.g., a rectangle, a plurality of fingers 122. Ground pattern 121 may be formed by any suitable process, including sputtering and patterning a seed layer on top of the oxide layer by lift off to form a ground plane 121. Alternately, ground plane 121 may also be formed by sputtering a seed, patterning with photoresist, electroplating a metal, e.g., gold (Au) and/or copper (Cu), stripping the photoresist and etching the seed layer.

It is to be appreciated that fingers 122 are non-linear, e.g., “bent” to the right. After further processing, described below, these shapes will become the shape of individual electronic probes. Such a shape, in conjunction with other factors, including cross-sectional geometry and material, may enable a spring characteristic for the individual electronic probes, advantageously improving compliance to and contact with integrated circuit test points.

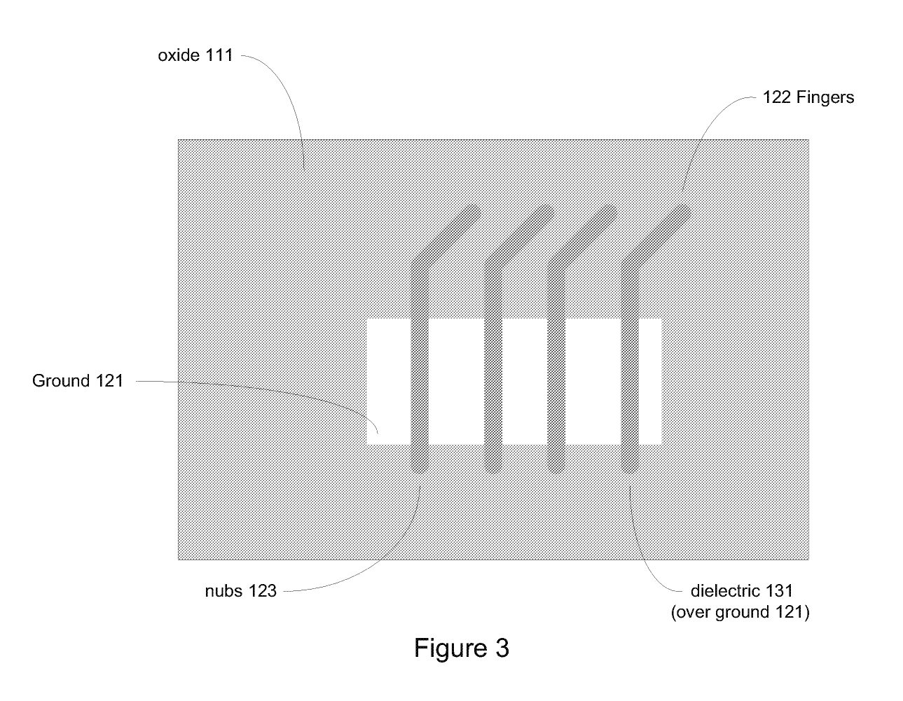

FIG. 3 illustrates a plan view of an exemplary patterned dielectric 131, e.g., an oxide, polymer, nitride, and the like, deposited on top of a portion of the ground pattern 121, including the fingers 122, in accordance with embodiments of the present invention. In addition, dielectric 131 is patterned to form nubs 123. It is appreciated that insulator 131 is deposited only over portions of the ground pattern 121 and nubs 123, e.g., it is not deposited over the entire substrate. Vias (not shown) are etched in the oxide layer 131 as required for subsequent layers to facilitate a connection to the ground plane 121.

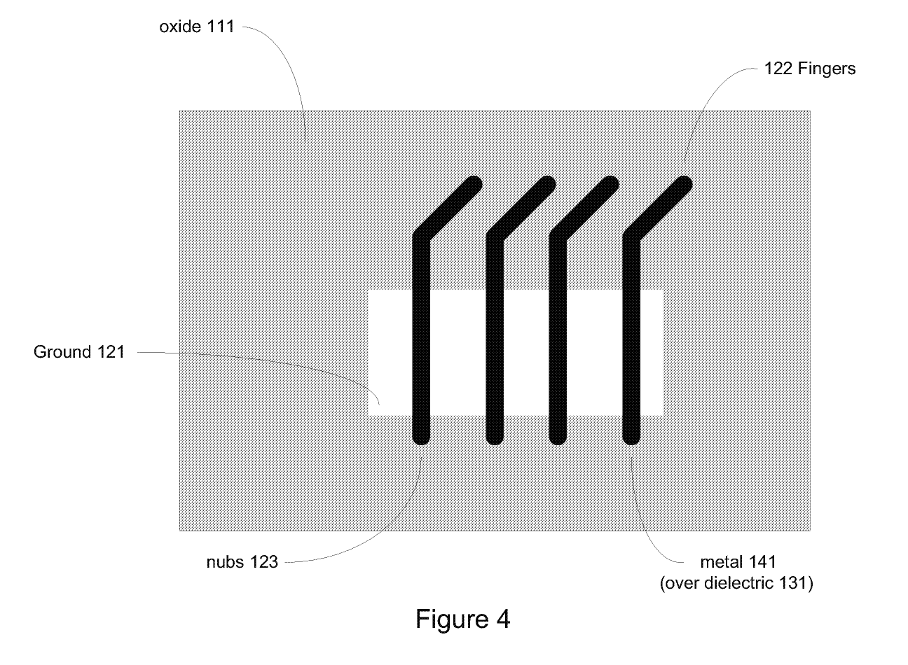

FIG. 4 illustrates a plan view of an exemplary patterned probe metal 141 on top of the oxide layer 131, in accordance with embodiments of the present invention. Probe metal 141 comprises any suitable material, e.g., a nickel-cobalt (NiCo) or nickel-manganese (NiMn) alloy, deposited by any suitable process. For example, a seed layer may be deposited on top of the oxide 111 on substrate 100. A lithographic pattern is defined and a suitable probe material 141 electroplated in the mold. It is advantageous for the probe metal 141, in combination with its three-dimensional geometry, to have a spring characteristic, e.g., to deform without yielding, and to apply a restoration force. The probe metal 141 may be polished in the mold for a smoother finish and also to form a level surface for subsequent operations.

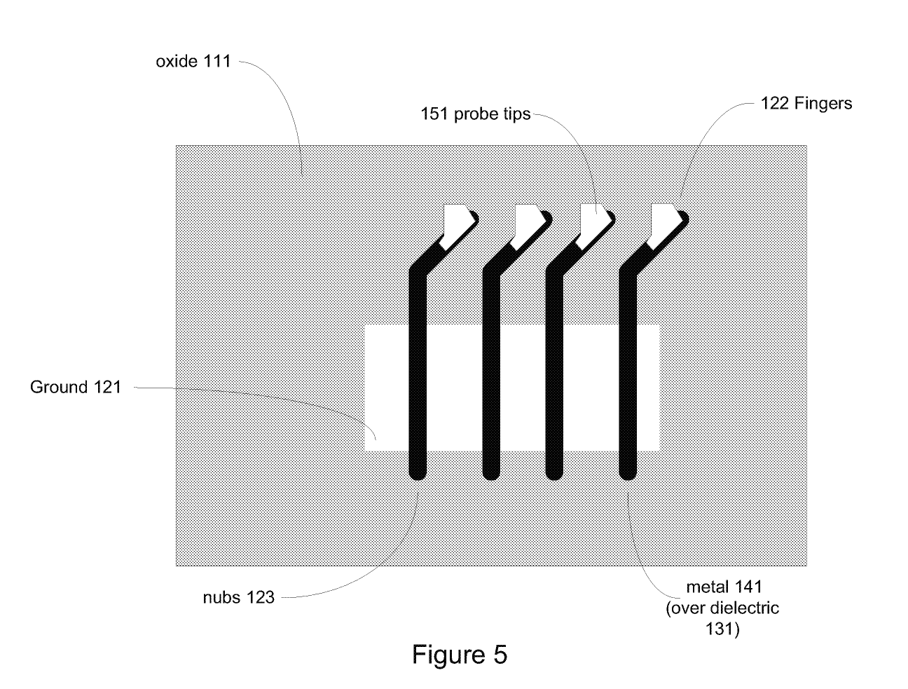

FIG. 5 illustrates a plan view of an exemplary application of a patterned probe tip 151 over probe metal 141, in accordance with embodiments of the present invention. A seed layer is deposited on top of the polished surface and a probe tip 151 is patterned and plated with a suitable material. The probe tip material 151 should be suitable for contacting a test point of an integrated circuit, for example, a noble metal, e.g., ruthenium (Ru), rhodium (Rh), palladium (Pd), silver (Ag), osmium (Os), iridium (Ir) and/or platinum (Pt). (It is appreciated that gold (Au) is often included in the noble metals, but is generally considered too soft for probing.) It is to be appreciated that probe tip 151 may extend beyond a projection of, e.g., overhang, probe metal 141, in either dimension, in some embodiments.

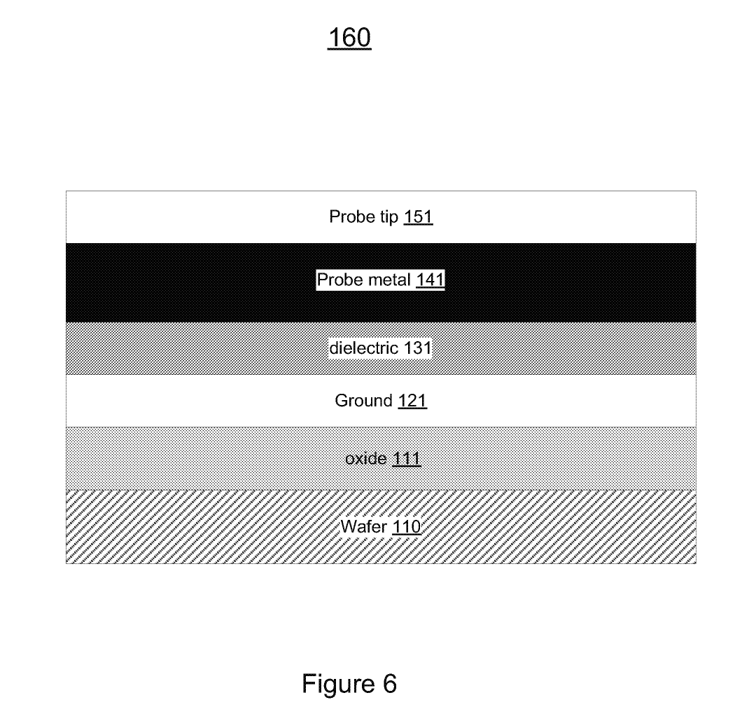

FIG. 6 illustrates a cross sectional view 160 of an exemplary probe finger 122 at the tip, in accordance with embodiments of the present invention. Probe tip 151, e.g., comprising rhodium (Rh), is located on top of probe metal 141, e.g., comprising nickel-manganese (NiMn), is located over a layer of oxide 131, which is deposited over a ground layer 121, which is located over an oxide 111 which is located over a wafer substrate 100. It is to be appreciated that ground plan 121 is parallel to probe metal 141. In addition, ground plane 121 is DC isolated from probe metal 141. However, ground plane 121 is physically close to probe metal 141, being separated by the thin oxide layer 131, for example, about 1-2 μm thick, and thus able to form an AC shield, e.g., at ground potential, for signals on probe metal 141.

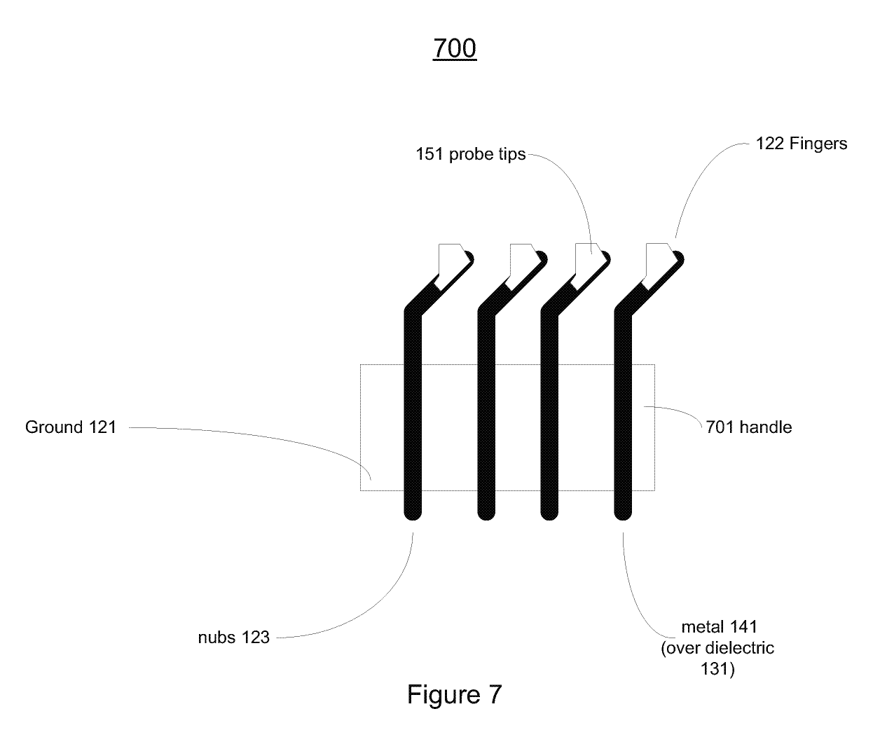

FIG. 7 illustrates a plan view of an exemplary row 700 of probes, in accordance with embodiments of the present invention. It is appreciated that the substrate 100, and insulator 101, have been removed except for that area under the ground plane 121, leaving a handle 701. The fingers 122 and nubs 123 are flying. The handle 701 is designed in such a way that a short stem of the probe is left behind to facilitate soldering the array to a space transformer.

Row of probes 700 may be formed by any suitable process. For example, the wafer is flipped and patterned with photoresist to define the handle 701. The wafer is then subjected to deep reactive ion etching (deep RIE), and the substrate is etched all the way down to form an array of probes 700 with a handle 701. The wafer is then sectioned into individual probe arrays, e.g., using a laser.

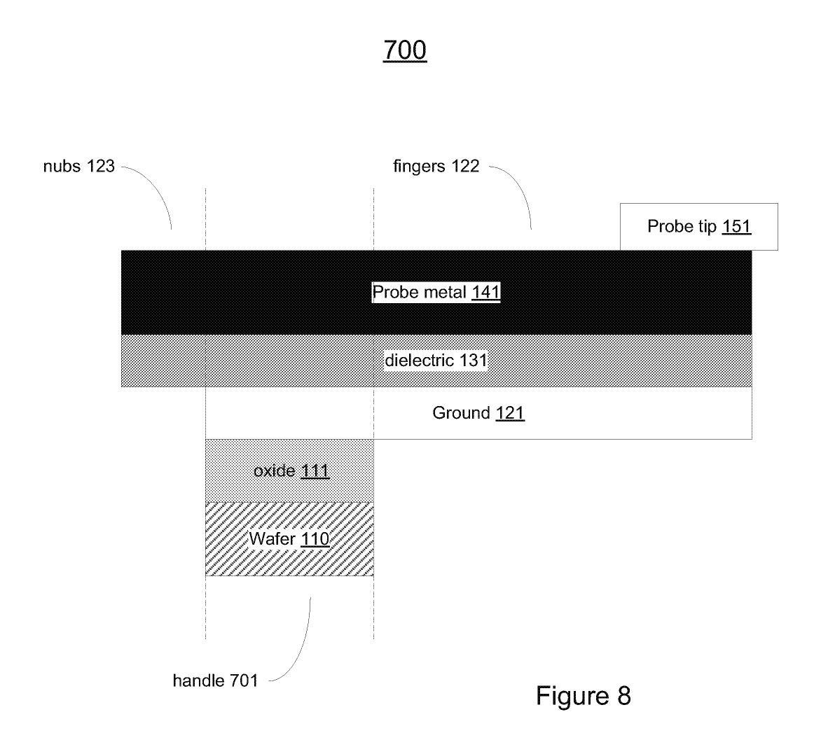

FIG. 8 illustrates a cross sectional view of exemplary row 700 of probes, in accordance with embodiments of the present invention. It is appreciated that the wafer 100 and oxide 111 layers have been reduces in horizontal extent, leaving the fingers 122 and nubs 123 flying.

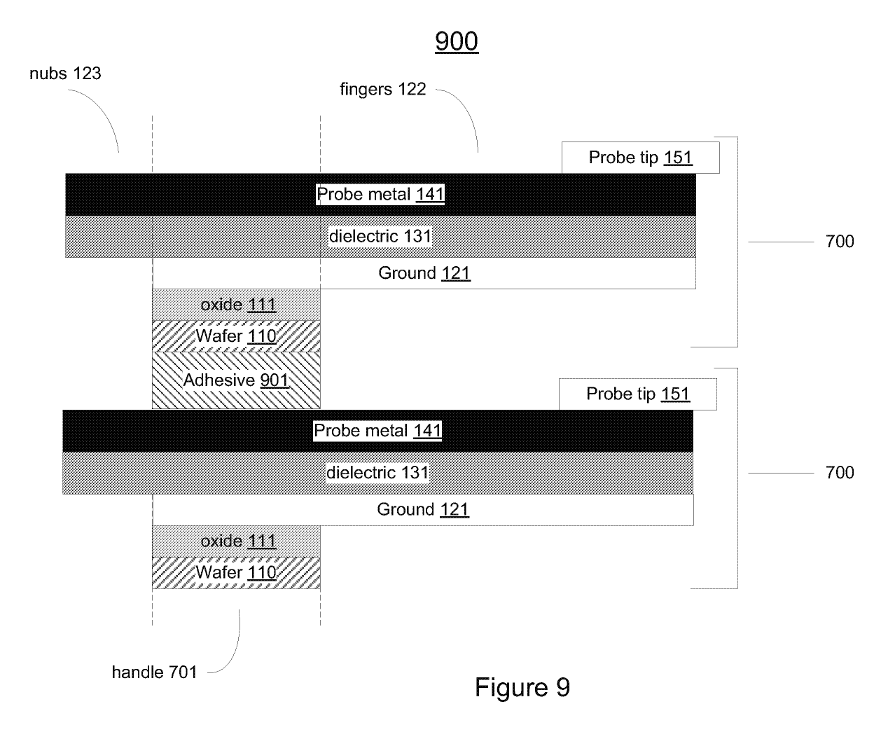

FIG. 9 illustrates a cross sectional view of an exemplary stack 900 of a plurality of rows of probes 700, in accordance with embodiments of the present invention. Adhesive 901 is applied in the handle area of the probe leaf and the rows 700 are stacked at defined vertical, or Z, dimension intervals using, e.g., a precision die attach machine. The Z stacking interval defines the probe pitch in the Y direction of a three dimensional probe array.

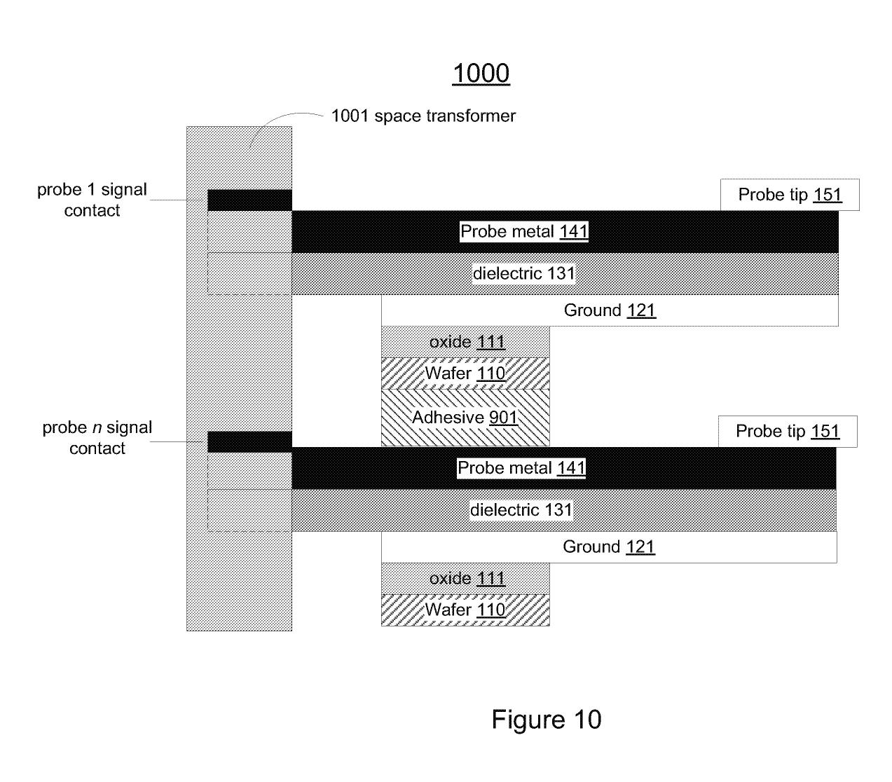

FIG. 10 illustrates a cross sectional view of an exemplary shielded probe array 1000, in accordance with embodiments of the present invention. The nubs 123 of stack 900 are electrically and mechanically attached to a space transformer 1001, e.g., via soldering. Space transformer 1001 supports the probes and provides an electrical path for the probe signals and ground. Typically, space transformer 1001 will have contacts on a non-probe face, e.g., to the left in FIG. 10, suitable for attaching to a printed circuit board or other higher level electronic assembly, at a pitch, e.g., contact to contact spacing, that is greater than the probe pitch.

It is to be appreciated that ground 121 is not present in the nubs 123 region, as previously described, in some embodiments. In accordance with embodiments of the present invention, the lack of ground 121 in nubs 123 may beneficially reduce interconnect density for space transformer 1001, and prevent shorting of signals to ground in the region of the interconnection. The ground plane 121 on the stack 900, e.g., in the region of the handle 701, may be coupled through vias in the oxide 131, as previously described with respect to FIG. 3, to a plurality of ground probes (which are part of the probe array) which are in turn coupled to the space transformer 1001.

Embodiments in accordance with the present invention simplify and improve assembly of fine pitch probe arrays by enabling handling of a row or leaf of probes instead of individual probes, as is typical under the conventional art. Embodiments in accordance with the present invention also enable high frequency testing with good signal integrity and low cross talk by supplying a ground plane electrically close to each probe.

Embodiments in accordance with the present invention further allow for silicon to be used as a probe material. The method of stacking can be applied to silicon leaves with a conductive trace layer on one side and a ground layer under oxide on the other side. Embodiments in accordance with the present invention are well suited to many integrated circuit testing applications, as the number of layers to be stacked is minimal and long arrays of probes may be fabricated on silicon.

Embodiments in accordance with the present invention provide systems and methods for shielded probe arrays. In addition, embodiments in accordance with the present invention provide systems and methods for shielded probe arrays that provide an electrically grounded shielded at fine pitch geometries. Further, embodiments in accordance with the present invention provide systems and methods for shielded probe arrays that are compatible and complementary with existing systems and methods of integrated circuit design, manufacturing and test.

Various embodiments of the invention are thus described. While the present invention has been described in particular embodiments, it should be appreciated that the invention should not be construed as limited by such embodiments, but rather construed according to the below claims.

What is claimed is:

1. An article of manufacture comprising:
a plurality of rows of electronic probes, each said row comprising:
a plurality of said electronic probes substantially in a plane, each said electronic probe comprising:
a metal signal layer and a ground layer, separated by an insulator;
a space transformer for mechanically supporting said plurality of rows of electronic probes; and
said space transformer also for providing an electrical path from each of said probe metal signal layers and said probe ground layer to a higher level electronic assembly.

2. The article of manufacture of claim 1 wherein each of said plurality of rows of electronic probes further comprises a handle comprising a substrate for handling said row of electronic probes.

3. The article of manufacture of claim 2 wherein said handle is configured for a die stacking apparatus to grasp and manipulate said row of electronic probes.

4. The article of manufacture of claim 1 wherein each said electronic probe further comprises a probe tip configured for contacting a test point of an integrated circuit.

5. The article of manufacture of claim 4 wherein said probe tip extends beyond a projection of said metal signal layer.

6. The article of manufacture of claim 1 wherein said rows of electronic probes are characterized as having a probe pitch, and said space transformer further comprises contacts for making electrical contact with said higher level electronic assembly, wherein said contacts are at a pitch greater than said probe pitch.

7. The article of manufacture of claim 1 wherein each said electronic probe is substantially non-linear in extent.

8. The article of manufacture of claim 1 wherein each said electronic probe exhibits a spring restoration force when deformed.

9. A method comprising:
coating a substrate with an insulating layer;
depositing a first conductive pattern, including an area pattern and a plurality of finger patterns, onto said insulating layer, said fingers patterns separate from one another but electrically coupled to said area pattern;
applying a dielectric pattern on top of said conductive pattern, said dielectric pattern substantially conforming to said finger patterns, and extending a pattern of said fingers across and beyond said area pattern to form a nub pattern;
plating a second conductive pattern on top of and coincident to said dielectric pattern;
plating a probe tip on top of said second conductive pattern; and
removing portions of said substrate and said insulating area under said finger pattern and said nub pattern to form a row of probes.

10. The method of claim 9 further comprising:
applying an adhesive to said row of probes; and
stacking a plurality of said row of probes to form an array of probes, wherein all said probe tips form a plane substantially perpendicular to a plane of one of said finger patterns.

11. The method of claim 10 wherein said stacking comprises gripping each row of said plurality of said row of probes by a remaining portion of said substrate.

12. The method of claim 10 further comprising assembling said nubs of said array of probes into a space transformer, wherein said space transformer is configured to make individual electrical contact with material of each said second conductive pattern of each said probe.

13. The method of claim 12 wherein said space transformer is further configured to make electrical contact with material of said first conductive pattern, isolated from said material of said second conductive pattern

14. The method of claim 9 wherein said probe tip is configured for contacting a test point of an integrated circuit.

15. The method of claim 9 wherein each said finger pattern is substantially non-linear in extent.

16. The method of claim 9 wherein said probes exhibits a spring restoration force when deformed.

17. An array of shielded probes for probing an integrated circuit comprising:
at least two probes, characterized as being separated by a probe pitch distance, each of said probes comprising:
a signal conductor and a shield conductor, electrically isolated from each other;
a probe tip, electrically connected to said signal conductor, comprising a different material from said signal conductor;
a space transformer for coupling signals from said at least two signal conductors to contacts separated by greater than said probe pitch distance.

18. The array of shielded probes of claim 17 wherein said shield conductor provides a majority of the mechanical support for said probe.

19. The array of shielded probes of claim 18 wherein said shield conductor exhibits a spring restoration force when deformed.

20. The array of shielded probes of claim 17 comprising at least three said probe tips, wherein said at least three probe tips from a plane substantially parallel to said space transformer.
